(19) United States
(12) Patent Application Publication
(10) Pub. No.: US 2009/0244864 A1
(43) Pub. Date: Oct. 1, 2009

(54) Substrate for capacitor-embedded printed circuit board, capacitor-embedded printed circuit board and manufacturing method thereof

(75) Inventors: Woon-Chun Kim, Suwon-si (KR); Sung Yi, Suwon-si (KR); Hwa-Sun Park, Suwon-si (KR); Sang-Chul Lee, Gunpo-si (KR); Jong-Woo Han, Seongnam-si (KR); Young-Do Kweon, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/320,794

(22) Filed: Feb. 4, 2009

(30) Foreign Application Priority Data
Mar. 25, 2008 (KR) 10-2008-0027551

(51) Int. Cl. H05K 1/18; B32B 7/00; B32B 37/02

(52) U.S. Cl. 361/763; 428/141; 156/313; 174/260

(57) ABSTRACT

Disclosed are a substrate for a capacitor-embedded printed circuit board, a capacitor-embedded printed circuit board, and a manufacturing method thereof. The capacitor-embedded printed circuit board can include a core board, an insulation resin layer, which is stacked on the core board, a first electrode and a first circuit pattern, which are buried in the insulation resin layer, a dielectric layer, which is stacked on a surface of the insulation resin layer, a first adhesive resin layer, which is stacked on the dielectric layer, and a second electrode and a second circuit pattern, which are formed on a surface of the first adhesive resin layer to correspond with the first electrode. With the present invention, the manufacturing process can be simplified and the reliability of products can be improved by reducing the variation of the capacitor (C).

### CROSS-REFERENCE TO RELATED APPLICATIONS

This application claims the benefit of Korean Patent Application No. 10-2008-0027551, filed with the Korean Intellectual Property Office on Mar. 25, 2008, the disclosure of which is incorporated herein by reference in its entirety.

### BACKGROUND

1. Technical Field

The present invention relates to a substrate for a capacitor-embedded printed circuit board, a capacitor-embedded printed circuit board, and a manufacturing method thereof.

2. Description of the Related Art

For today's electronic appliances, including portable devices, an increasing number of consumers have been placing a wider variety of demands. In particular, the consumers are pressuring the designers and manufacturers for new devices that are more multifunctional, compact, light-weight, high-speed, inexpensive, mobile, internet-accessible wirelessly and fashionable. As a result of this intense competition, new models hit the market more quickly, and the shortened life cycle of new models adds more pressure to the designers and manufacturers.

Accordingly, the number of passive components is increased with the boosted number of ICs due to the diversified functions in a product, making a portable apparatus bulkier. An electronic appliance typically has a plurality of active components and passive components mounted on a printed circuit board. Particularly, a large number of passive components are mounted in the form of a discrete chip capacitor on the surface of a printed circuit board in order to allow signals to be smoothly transferred.

Many companies are developing an embedded printed circuit board to increase the density of an electronic system. The passive parts embedded in the board include L. R and C types. However, the separate-chip-type passive parts have not been successful in making a product compact, light and thin, space-efficient and cost-effective.

While there are various ways to realize an embedded capacitor, there has been much attention to realizing the embedded capacitor by use of an RCC-type material, for which the thickness can be easily adjusted. However, since the RCC-type material has a poor laminating property, it requires an additional process of smoothing the surface, on which the RCC-type material is laminated.

This type of structural problem of the RCC-type material causes a circuit pattern thickness of the laminated surface to be largely varied or a dielectric substance of the RCC-type material to be largely varied with respect to the thickness of resin, in spite of the additional process of smoothing the laminated surface. Sometimes, this results in defect such as delamination of the laminated surface.

### SUMMARY

The present invention provides a capacitor, a substrate for a capacitor-embedded printed circuit board, a capacitor-embedded printed circuit board, and a manufacturing method thereof that can simplify the manufacturing process and reduce the variation of capacitance (C) to improve the product reliability.

An aspect of the invention provides a substrate for a capacitor-embedded printed circuit board including a dielectric layer; and a first adhesive resin layer, configured to be stacked on a surface of the dielectric layer. Here, roughness can be formed on the first adhesive resin layer.

The substrate can further include a second adhesive resin layer, configured to be stacked on another surface of the dielectric layer. Here, roughness can be formed on the second adhesive resin layer. At this time, the substrate can further include a first metal layer, configured to be stacked on the first adhesive resin layer. The substrate can further include a second metal layer, configured to be stacked on the second adhesive resin layer.

Another aspect of the invention provides a capacitor-embedded printed circuit bard including a core board; an insulation resin layer, configured to be stacked on the core board; a first electrode and a first circuit pattern, configured to be buried in the insulation resin layer; a dielectric layer, configured to be stacked on a surface of the insulation resin layer; a first adhesive resin layer, configured to be stacked on the dielectric layer; and a second electrode and a second circuit pattern, configured to be formed on a surface of the first adhesive resin layer to correspond with the first electrode.

The first adhesive resin layer can be desmeared. The printed circuit board can further include a second adhesive resin layer, configured to be interposed between the insulation resin layer and the dielectric layer. The second adhesive resin can be desmeared.

Also, the printed circuit board can further include an insulation board, configured to be stacked on the first adhesive resin layer to cover the second electrode; a third circuit pattern, configured to be formed on a surface of the insulation board; and a via, configured to pass through the insulation board.

Another aspect of the invention provides a method of manufacturing a capacitor-embedded printed circuit board including providing a substrate on which a first metal layer, a dielectric layer and an adhesive resin layer are stacked on the order thereof; etching a part of the first metal layer to form a first electrode and a first circuit pattern; compressing a surface of the substrate, on which the first electrode is formed, onto a core board by interposing an insulation resin layer; forming a second electrode and a second circuit pattern on the adhesive resin layer; stacking an insulation board on the substrate such that the second electrode and the second circuit pattern are covered; and forming a third circuit pattern on the insulation board

A second metal layer can be stacked on the adhesive resin layer, and in the forming the second electrode and the second circuit pattern, a part of the second metal layer can be etched.

Also, the method can further include desmearing the adhesive resin layer, prior to the stacking the insulation board. At this time, the forming the second electrode and the second circuit pattern can include forming a seed layer on the desmeared adhesive resin layer; forming a plating resist on the seed layer; forming a plating layer corresponding to the second electrode and the second circuit pattern through electroplating; removing the plating resist; and performing flash-etching such that a part of the seed layer is removed.

However, the forming the second electrode and the second circuit pattern can be performed before the compressing a surface of the substrate onto a core board.

Also, two substrates can be provided, and the compressing a surface of the substrate onto a core board can be performed on both surfaces of the core board.

Another aspect of the invention provides a method of manufacturing a capacitor-embedded printed circuit board including providing a substrate on which a first metal layer, a first adhesive resin layer, a dielectric layer and a second adhesive resin layer are stacked on the order thereof; etching a part of the first metal layer to form a first electrode and a first circuit pattern; esmearing the first adhesive resin layer; compressing a surface of the substrate, on which the first electrode is formed, onto a core board by interposing an insulation resin layer; forming a second electrode and a second circuit pattern on the second adhesive resin layer; stacking an insulation board on the substrate such that the second electrode and the second circuit pattern are covered; and forming a third circuit pattern on the insulation board.

A second metal layer can be stacked on the second adhesive resin layer, and in the forming the second electrode and the second circuit pattern, a part of the second metal layer can be etched.

The method can further include desmearing the second adhesive resin layer, prior to the stacking the insulation board. The forming the second electrode and the second circuit pattern can include forming a seed layer on the desmeared second adhesive resin layer; forming a plating resist on the seed layer; forming a plating layer corresponding to the second electrode and the second circuit pattern through electroplating; removing the plating resist; and performing flash-etching such that a part of the seed layer is removed.

The forming the second electrode and the second circuit pattern can be performed before the compressing a surface of the substrate onto a core board. Two substrates can be provided, and the compressing a surface of the substrate onto a core board can be performed on both surfaces of the core board.

Another aspect of the invention provides a method of manufacturing a capacitor-embedded printed circuit board including providing a substrate on which a first adhesive resin layer, a dielectric layer and a second adhesive resin layer are stacked on the order thereof; desmearing the first adhesive resin layer; forming a first electrode and a first circuit pattern on the desmeared first adhesive resin layer through a plating process; compressing a surface of the substrate, on which the first electrode is formed, onto a core board by interposing an insulation resin layer; forming a second electrode and a second circuit pattern on the second adhesive resin layer; stacking an insulation board on the substrate such that the second electrode and the second circuit pattern are covered; and forming a third circuit pattern on the insulation board.

The method can further include desmearing the second adhesive resin layer, prior to the stacking the insulation board. Here, the forming the second electrode and the second circuit pattern can be performed through a plating process.

Also, the forming the second electrode and the second circuit pattern can be performed before the compressing a surface of the substrate on to a core board. Two substrates can be provided, and the compressing a surface of the substrate can be performed on both surfaces of the core board.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a sectional view showing a first embodiment of a substrate for a capacitor-embedded printed circuit board in accordance with an aspect of the present invention;

FIG. 2 is a sectional view showing a second embodiment of a substrate for a capacitor-embedded printed circuit board in accordance with an aspect of the present invention;

FIG. 3 is a sectional view showing a-third embodiment of a substrate for a capacitor-embedded printed circuit board in accordance with an aspect of the present invention;

FIG. 4 is a sectional view showing a fourth embodiment of a substrate for a capacitor-embedded printed circuit board in accordance with an aspect of the present invention;

FIG. 5 is a sectional view showing a first embodiment of a capacitor-embedded printed circuit board in accordance with another aspect of the present invention;

FIG. 6 is a sectional view showing a second embodiment of a capacitor-embedded printed circuit board in accordance with another aspect of the present invention;

FIG. 7 is a flowchart showing a first embodiment of a manufacturing method of a capacitor-embedded printed circuit board in accordance with another aspect of the present invention;

FIG. 8 through FIG. 19 show each process of the manufacturing method of FIG. 7;

FIG. 20 is a flowchart showing a second embodiment of a manufacturing method of a capacitor-embedded printed circuit board in accordance with another aspect of the present invention;

FIG. 21 through FIG. 28 show each process of the manufacturing method of FIG. 20;

FIG. 29 is a flowchart showing a third embodiment of a manufacturing method of a capacitor-embedded printed circuit board in accordance with another aspect of the present invention;

FIG. 30 through FIG. 42 show each process of the manufacturing method of FIG. 29;

FIG. 43 is a flowchart showing a fourth embodiment of a manufacturing method of a capacitor-embedded printed circuit board in accordance with another aspect of the present invention;

FIG. 44 through FIG. 52 show each process of the manufacturing method of FIG. 43;

FIG. 53 is a flowchart showing a fifth embodiment of a manufacturing method of a capacitor-embedded printed circuit board in accordance with another aspect of the present invention; and

FIG. 54 through FIG. 66 show each process of the manufacturing method of FIG. 53.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. Throughout the drawings, similar elements are given similar reference numerals. Throughout the description of the present invention, when describing a certain technology is determined to evade the point of the present invention, the pertinent detailed description will be omitted.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, some embodiments of a capacitor-embedded printed circuit board and a manufacturing method thereof in accordance with an embodiment of the present invention will be described in detail with reference to the accompanying drawings. Those components that are the same or are in correspondence are rendered the same reference numeral regardless of the figure number, and redundant explanations are omitted.

Firstly, a substrate for a capacitor-embedded printed circuit board will be described in accordance with an aspect of the present invention.

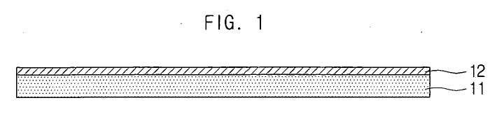

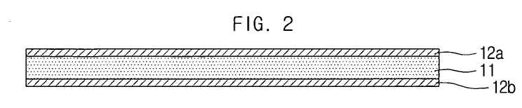

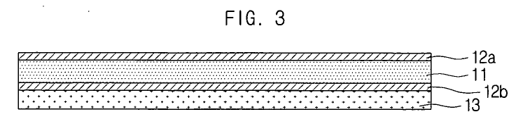

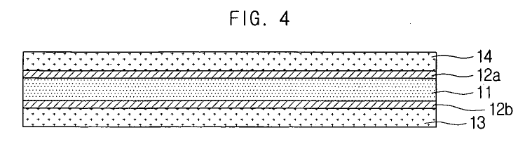

FIG. 1 is a sectional view showing a first embodiment of a substrate for a capacitor-embedded printed circuit board in accordance with an aspect of the present invention, and FIG. 2 is a sectional view showing a second embodiment of a substrate for a capacitor-embedded printed circuit board in accordance with an aspect of the present invention. FIG. 3 is a sectional view showing a third embodiment of a substrate for a capacitor-embedded printed circuit board in accordance with an aspect of the present invention, and FIG. 4 is a sectional view showing a fourth embodiment of a substrate for a capacitor-embedded printed circuit board in accordance with an aspect of the present invention. Referring to FIG. 1 through FIG. 4, a dielectric layer 11, an adhesive resin layer 12 or 12a and 12b and a metal layer 13 or/and 14 are shown.

The substrate according to the first embodiment can be formed by allowing the adhesive resin layer 12 to be stacked on a surface of the dielectric layer 11. Here, the adhesive resin layer 12 can made of a material capable of being formed with the roughness. At this time, the dielectric layer 11 can be in a semi-hardened status (B-stage) or a hardened status (C-stage).

The adhesive resin layer 12 can be stacked to have a couple of micrometers of thickness on the dielectric layer 11. As described above, the adhesive resin layer 12 suggested by the embodiment can be made of a material capable of being formed with the roughness through desmearing. For example, the material capable of being formed with the roughness can be an adhesive mentioned in the Korean patent publication No. 2007-0078086 (filed by Mitsubishi Gas Chemical Company). Of course, any material capable of being formed with the roughness is applicable.

The adhesive resin layers 12a and 12b, as shown in FIG. 2, can be formed on each opposite surface of the dielectric layer 11, and as shown in FIG. 3, the metal layer 13 can be formed on one surface of the dielectric layer 11. In the case of the metal layer 13, it becomes unnecessary to perform an additional process such as a metal layer stacking process to form a lower electrode or an upper electrode of a capacitor included in the printed circuit board. The process of etching the pertinent metal layer makes it easy to form the electrode of the capacitor.

This kind of metal layer can be formed on one side surface of the dielectric layer 11 as shown in FIG. 3 or on each opposite surface of the dielectric layer 11 as shown in FIG. 4.

Then, a capacitor-embedded printed circuit board in accordance with another aspect of the present invention will be described.

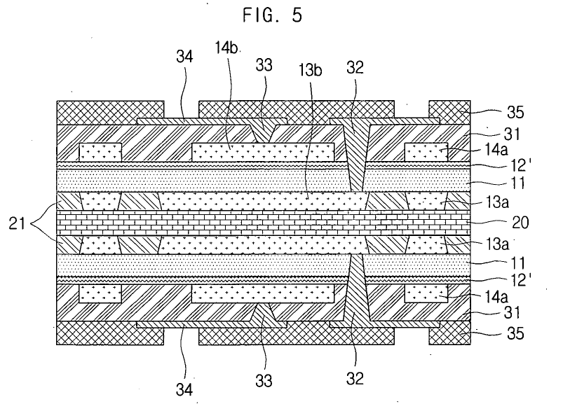

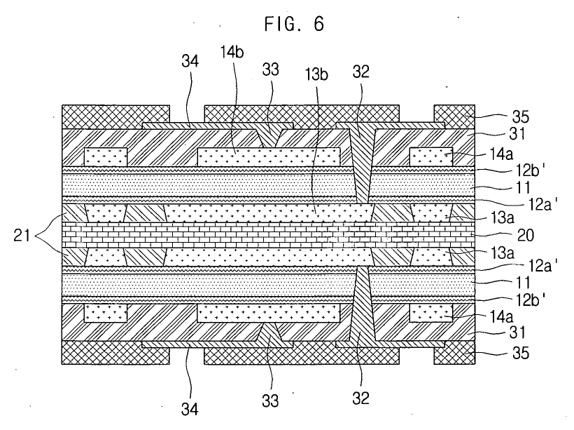

FIG. 5 is a sectional view showing a first embodiment of a capacitor-embedded printed circuit board in accordance with another aspect of the present invention, and FIG. 6 is a sectional view showing a second embodiment of a capacitor-embedded printed circuit board in accordance with another aspect of the present invention.

Referring to FIG. 5 and FIG. 6, a dielectric layer 11, an adhesive resin layer 12′, a first adhesive resin layer 12a′, a second adhesive resin layer 12b′, a first electrode 13a, a second electrode 14a, a first circuit pattern 13b, a second circuit pattern 14b, a core board 20, an insulation resin layer 21, an insulation board 31, a via 32 and 33, a third circuit pattern 34 and a solder resist 35 are shown.

In the case of the printed circuit board as shown in FIG. 5, it is possible to realize a capacitor in which the first electrode 13a, the dielectric layer 11, the adhesive resin layer 12′, the second electrode 14a are formed in an pattern.

The capacitor-embedded printed circuit board of the above-described structure can minimize the possibility of the delamination that may happen at an area in which the insulation board 31 is stacked by the adhesive resin layer 12′ formed with the roughness, to thereby improve the reliability of products.

Also, forming the adhesive resin layer 12′ as a thin film (having a couple of micrometers of thickness or less) makes it possible to minimize the effect that the adhesive resin layer 12′ has on the performance of the capacitor.

Even though FIG. 5 shows that the adhesive resin layer 12′ is formed on one side surface of the dielectric layer 11, the adhesive resin layers 12a′ and 12b′ can be formed on both surfaces of the dielectric layer 11 as shown in FIG. 6.

Hereinafter, the manufacturing method of the capacitor-embedded printed circuit board of the above-described structure will be described in more detail.

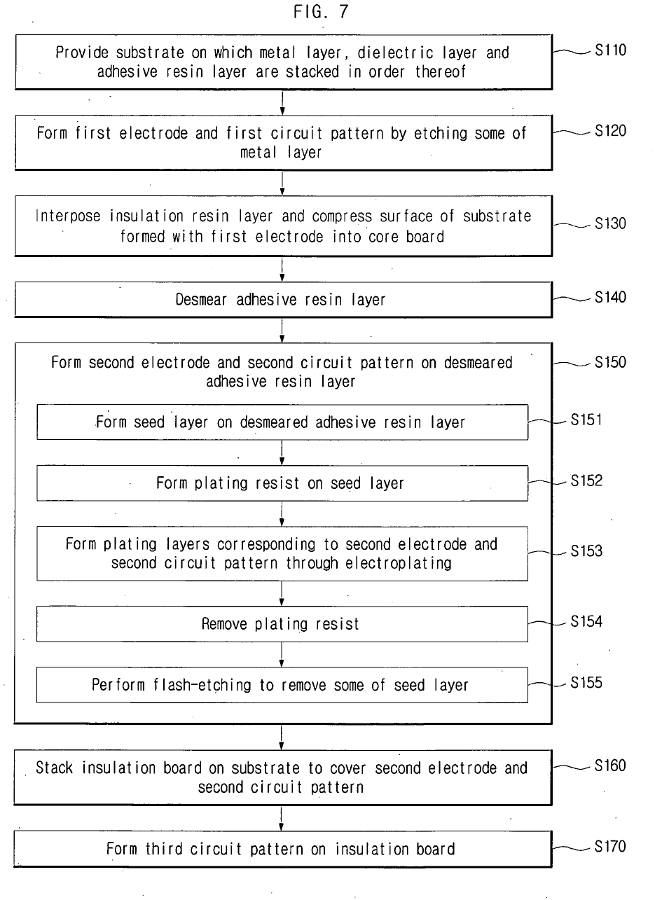

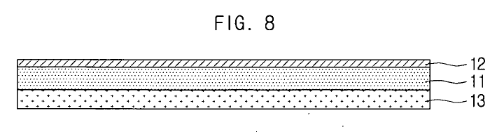

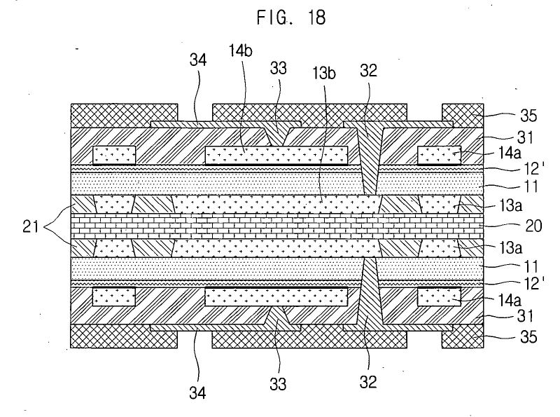

FIG. 7 is a flowchart showing a first embodiment of a manufacturing method of a capacitor-embedded printed circuit board in accordance with another aspect of the present invention, and FIG. 8 through FIG. 19 show each process of the manufacturing method of FIG. 7.

Referring to FIG. 8 through FIG. 19, a dielectric layer 11, an adhesive resin layer 12 and 12′, a metal layer 13, a first electrode 13a, a first circuit pattern 13b, a second electrode 14a, a second circuit pattern 14b, a seed layer 16, a plating resist 17, a core layer 20, an insulation resin layer 21, an insulation board 31, a via 32 and 33, an etching resist 35 are shown.

Firstly, as shown in FIG. 8, the metal layer 13, a substrate in which the metal layer 13, the dielectric layer 11 and the adhesive resin layer 12 are stacked on the order thereof can be provided in a step represented by S110. Here, the adhesive resin layer 12 can improve not only the adhesive power between the dielectric layer 11 and the metal layer 13 but also the adhesive power with the below-described insulation board 31 in order to enhance the reliability of products.

At this time, the adhesive resin layer 12 can be formed as a thin film to minimize the effect on the capacitance of the capacitor included in the board. For example, the adhesive resin layer 12 can be formed to have the thickness of 10 um or less.

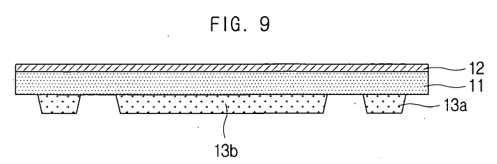

Then, as shown in FIG. 9, the first electrode 13a and the first circuit pattern 13b can be formed by etching some parts of the metal layer 13 in a step represented by S120. The first electrode 13a can function as the upper electrode or the lower electrode of the capacitor included in the printed circuit board in accordance with the embodiment. The position and size of the first electrode 13a can be changed in various ways according to designer's intention.

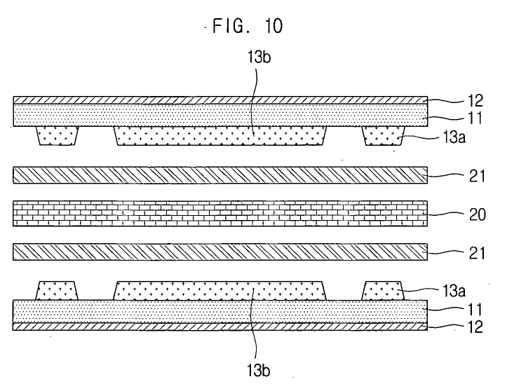

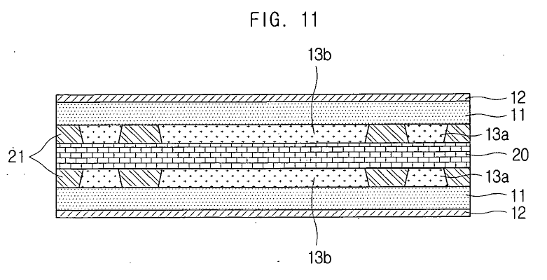

After that, as shown in FIG. 10 and FIG. 11, a surface of the substrate in which the first electrode 13a is formed can be compressed onto the core board 20 by interposing the insulation resin layer 21 in a step represented by S130. Alternatively, two substrates can be prepared to be compressed onto both surfaces of the core board 20. This process can make it possible to form the multi-structure.

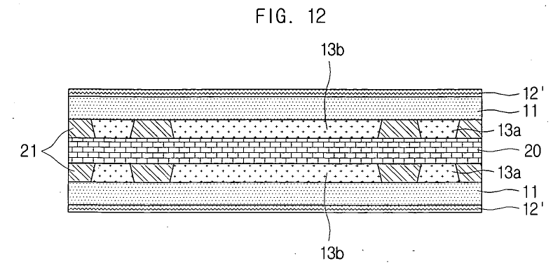

Then, as shown in FIG. 12, the adhesive resin layer 12 can be desmeared in a step represented by S140. Forming the roughness on the adhesive resin layer 12 through the desmearing can make it possible to allow the below-described seed layer 16 to be formed on the adhesive resin layer 12 more strongly. FIG. 12 shows the adhesive resin layer 12′ formed with the roughness.

After the desmearing is performed, the second electrode 14a and the second circuit pattern 14b can-be formed on the adhesive resin layer 12′ in a step represented by S150. The second electrode 14a can form the capacitor of the printed circuit board together with the above described first electrode 13a. In other words, if the first electrode 13a acts as the lower electrode, the second electrode 14a can act as the upper electrode. Accordingly, the second electrode 14a can be formed in consideration of the position and size of the first electrode 13a. Below is more detailedly described the method of forming the second electrode 14a and the circuit pattern 14b.

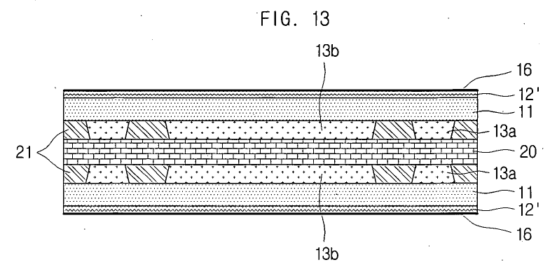

Firstly, as shown in FIG. 13, the seed layer 16 can be formed on the adhesive resin layer 12′ that has been desmeared in a step represented by S151. The seed layer 16 can be formed by a sputtering method or an electroless plating method.

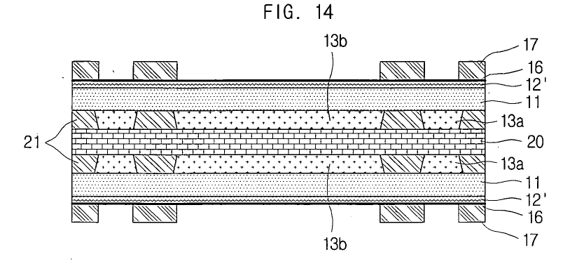

Then, as shown in FIG. 14, the plating resist 17 can be formed in a step presented by S152. It is possible to use a method of allowing a dry film (not shown) to be formed on the seed layer 16 and then an exposure/development process to be performed. Of course, the plating resist 17 can be formed in other various ways.

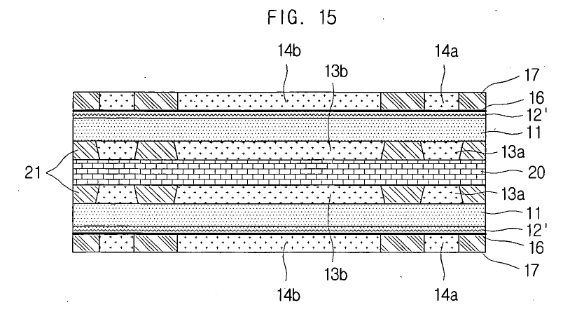

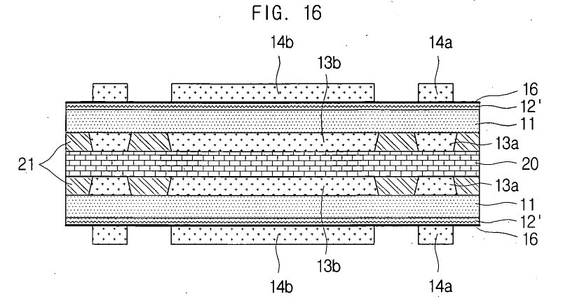

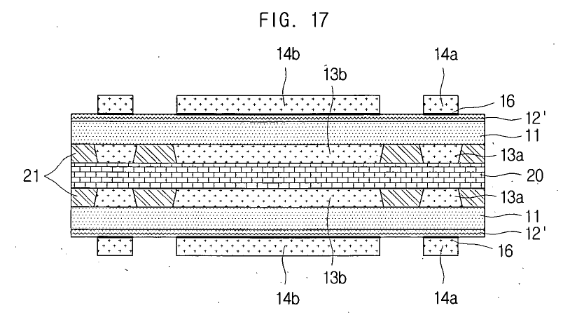

After that, as shown in FIG. 15, a plating layer corresponding to the second electrode 14a and the second circuit pattern 14b can be formed through the electroplating in a step represented by S153, and as shown FIG. 16, the plating resist 17 can be removed in a step represented by S154. Then, as shown in FIG. 17, forming the second electrode 14a and the second circuit pattern 14b as the pattern can be completed by performing the flash-etching to allow some parts of the seed layer 16 to be removed in a step represented by S155.

As a result, using the plating method to form the second electrode 14a can make it possible to form the electrode having a more accurate size, to thereby arrange the capacity of the capacitor accurately.

After the above-described process forms the second electrode 14a and the second circuit pattern 14b, the insulation board 31 can be stacked on the substrate so as to cover the second electrode 14a and the second circuit pattern 14b in a step represented by S160 and the third circuit pattern 34 can be formed on the insulation board 31 in a step represented by S170.

In addition to the third circuit pattern 34, the via 32 and 33 can be formed to allow each layer to be electrically connected and the solder resist 35 can be formed in the outermost layer to protect the third circuit pattern 34.

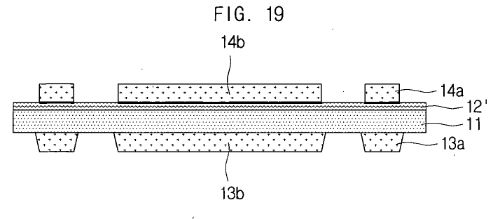

Although this embodiment suggests the method of allowing the substrate in which the first electrode 13a and the second circuit pattern 13b are formed to be stacked on the core board 20 and then the second electrode 14a and the second 14b to be formed, as shown FIG. 19, it may be alternatively possible to allow the first electrode 13a, the first circuit pattern 13b, the second electrode 14a and the second circuit pattern 14b to be formed on the substrate before the substrate is stacked on the core board 20.

Then, a second embodiment will be described.

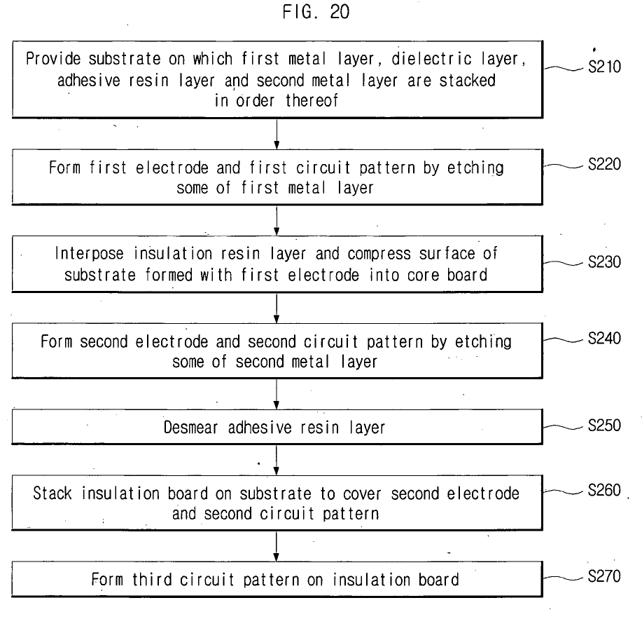

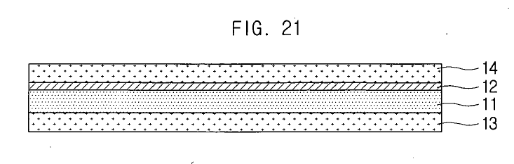

FIG. 20 is a flowchart showing a second embodiment of a manufacturing method of a capacitor-embedded printed circuit board in accordance with another aspect of the present invention, and FIG. 21 through FIG. 28 show each process of the manufacturing method of FIG. 20.

Referring to FIG. 21 through FIG. 28, a dielectric layer 11, an adhesive resin layer 12 and 12′, a first metal layer 13, a first electrode 13a, a first circuit pattern 13b, a second metal layer 14, a second electrode 14a, a second circuit pattern 14b, a core layer 20, an insulation resin layer 21, an insulation board 31, a via 32 and 33, a third circuit pattern 34 and an etching resist 35 are shown.

As compared with the above-described first embodiment, the difference is that the second electrode 14a and the second circuit pattern 14b can be formed by an etching method instead of the plating method in accordance with the second embodiment. The below description related to the embodiment focuses on the difference. The description related to identical or corresponding parts will be omitted.

Firstly, as shown in FIG. 21, the first metal layer 13, a substrate in which the dielectric layer 11, the adhesive resin layer 12 and the second metal layer 14 are stacked can be provided in a step represented by S210. As described above, since the second electrode 14a and the second circuit pattern 14b is formed by the etching method in accordance with the embodiment, the substrate in which the second metal layer 14 is stacked on the adhesive resin layer 12 can be used.

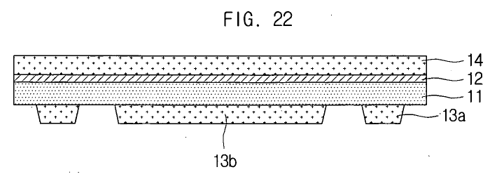

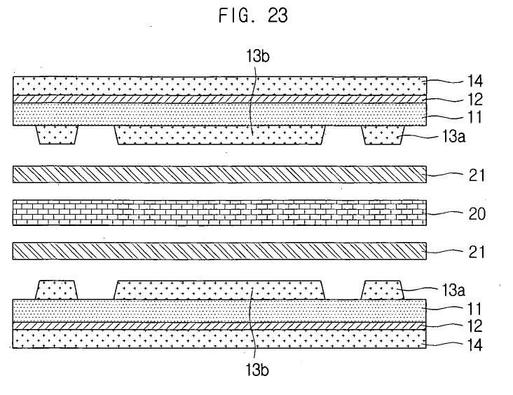

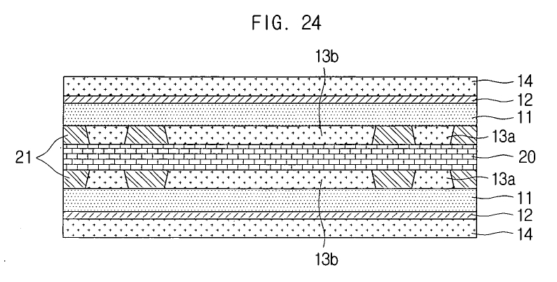

Then, as shown in FIG. 22, the first electrode 13a and the first circuit pattern 13b can be formed by etching some parts of the first metal layer 13 in a step represented by S220. After that, as shown in FIG. 23 and FIG. 24, the insulation-resin layer 21 can be interposed to allow a surface of the substrate in which the first electrode 13a is formed to be compressed onto the core board 20 in a step represented by S230.

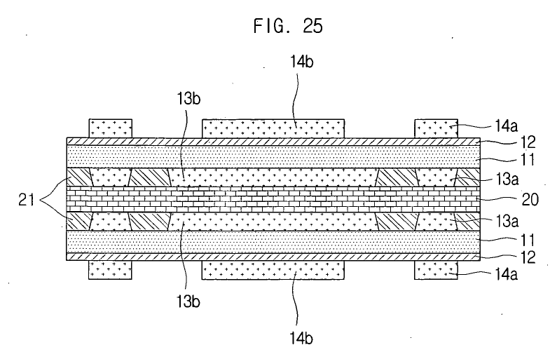

Next, as shown in FIG. 25, the second electrode 14a and the second circuit pattern 14b can be formed by etching some parts of the second metal layer 14 in a step represented by S240. The second electrode 14a can form a capacitor together with the above described first electrode 13a. In other words, if the first electrode 13a acts as the lower electrode, the second electrode 14a can act as the upper electrode. Accordingly, the second electrode 14a can be formed in consideration of the position and size of the first electrode 13a.

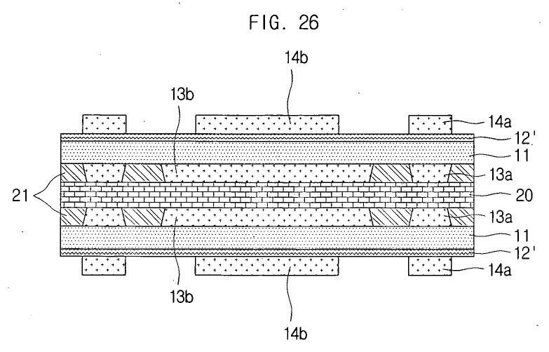

Then, as shown in FIG. 26, the adhesive resin layer 12 can be desmeared in a step represented by S250. Some parts of the second metal layer 14 can be etched to allow some surface of the adhesive resin layer 12 to be exposed to the outside. The roughness can be formed on the exposed surface of the adhesive resin layer 12. As a result, the formed roughness can make it possible to improve the adhesiveness to the insulation board 31 to be stacked later. This can minimize the possibility of the delamination, to thereby improve the reliability of products. FIG. 26 shows the adhesive resin layer 12′ formed with the roughness.

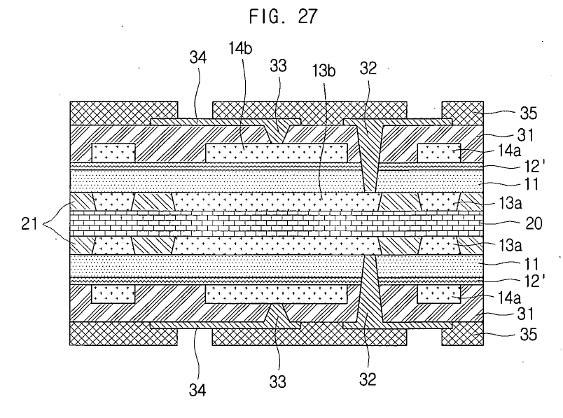

After that, as shown in FIG. 27, the insulation board 31 can be stacked on the substrate to cover the second electrode 14a and the second circuit pattern 14b in a step represented by S260, and the third circuit pattern 34 can be formed on the insulation board 31 in a step represented by S270. In addition to the third circuit pattern 34, the via 32 and 33 can be formed to allow each layer to be electrically connected and the solder resist 35 can be formed in the outermost layer to protect the third circuit pattern 34.

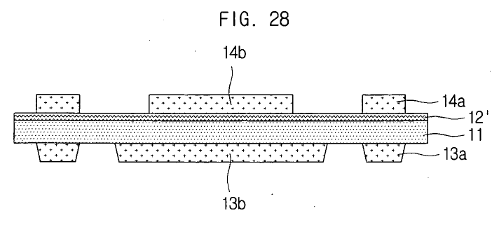

Although this embodiment suggests the method of allowing the substrate in which the first electrode 13a and the second circuit pattern 13b are formed to be stacked on the core board 20 and then the second electrode 14a and the second 14b to be formed, as shown FIG. 28, it may be alternatively possible to allow the first electrode 13a, the first circuit pattern 13b, the second electrode 14a and the second circuit pattern 14b to be formed on the substrate before the substrate is stacked on the core board 20.

Then, a third embodiment will be described.

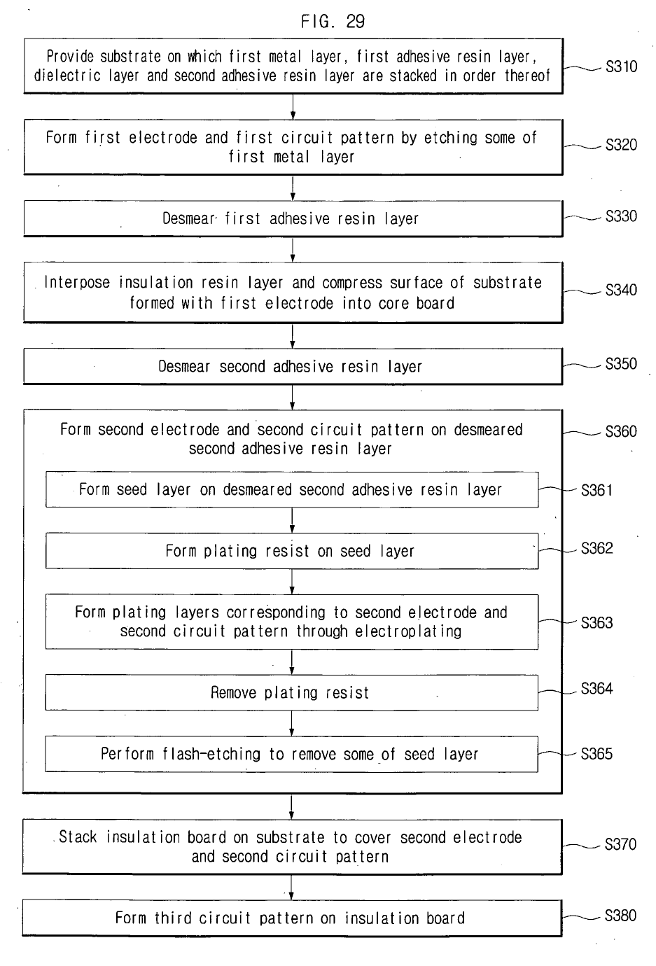

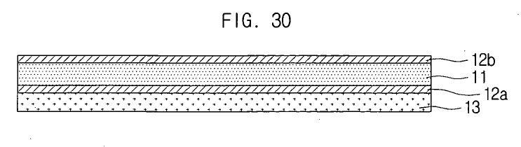

FIG. 29 is a flowchart showing a third embodiment of a manufacturing method of a capacitor-embedded printed circuit board in accordance with another aspect of the present invention, and FIG. 30 through FIG. 42 show each process of the manufacturing method of FIG. 29.

Referring to FIG. 30 through FIG. 42, a dielectric layer 11, a first adhesive resin layer 12a and 12a′, a second adhesive resin layer 12b and 12b′, a metal layer 13, a first electrode 13a, a first circuit pattern 13b, a second electrode 14a, a second circuit pattern 14b, a seed layer 16, a plating resist 17, a core layer 20, an insulation resin layer 21, an insulation board 31, a via 32 and 33, a third circuit pattern 34 and an etching resist 35 are shown.

As compared with the above-described first embodiment, the difference is that the adhesive resin layer 12a and 12b can be formed on both surfaces of the dielectric layer 11 in accordance with the third embodiment. The below description related to the embodiment focuses on the difference. The description related to identical or corresponding parts will be omitted.

Firstly, as shown in FIG. 30, a substrate in which the-first metal layer 13, the first adhesive resin layer 12a, a dielectric layer 11 and a second adhesive resin layer 12b are stacked on the order thereof can be used in a step represented by S310.

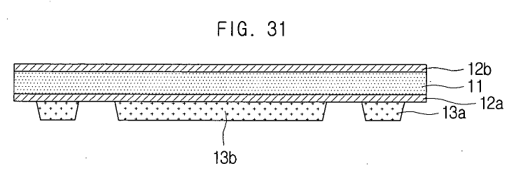

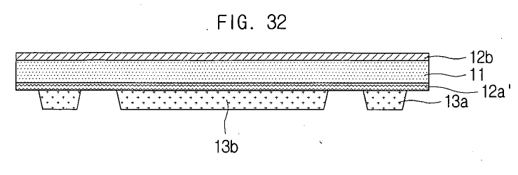

After that, as shown in FIG. 31, some of the first metal layer 13 can be etched to form the first electrode 13a and the first circuit pattern 13b in a step represented by S320. Then, as shown in FIG. 32, the first adhesive resin layer 12a can be desmeared in a step represented by S330.

Some parts of the first metal layer 13 stacked on the first adhesive resin layer 12a can be etched to allow some surface of the first adhesive resin layer 12a to be exposed to the outside. The roughness can be formed on the exposed surface of the first adhesive resin layer 12a. As a result, the formed roughness can make it possible to improve the adhesiveness to the insulation board 31 to be stacked later. This can minimize the possibility of the delamination, to thereby improve the reliability of products.

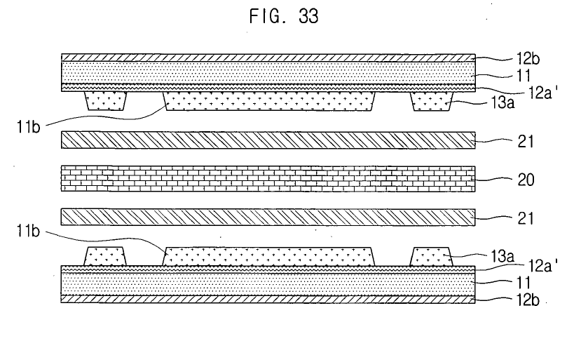

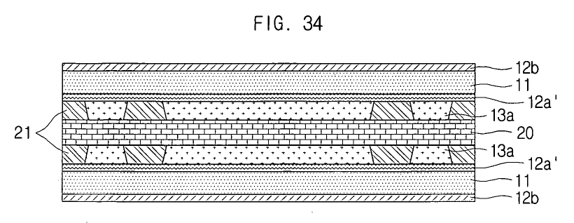

Then, as shown in FIG. 33 and FIG. 34, a surface of the substrate in which the first electrode 13a is formed can be compressed onto the core board 20 by interposing the insulation resin layer 21 in a step represented by S340. Alternatively, two substrates can be prepared to be compressed onto both surfaces of the core board 20. This process can make it possible to form the multi-structure.

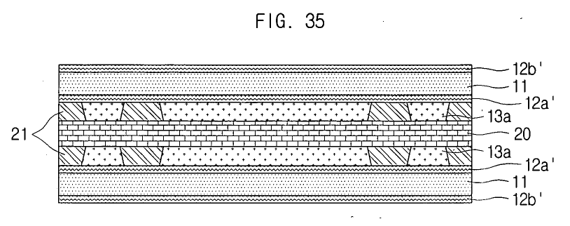

Then, as shown in FIG. 35, the second adhesive resin layer 12b can be desmeared in a step represented by S350. Forming the roughness on the second adhesive resin layer 12b through the desmearing can make it possible to allow the below-described seed layer 16 to be formed on the second adhesive resin layer 12b more strongly. FIG. 35 shows the adhesive resin layer 12b′ formed with the roughness.

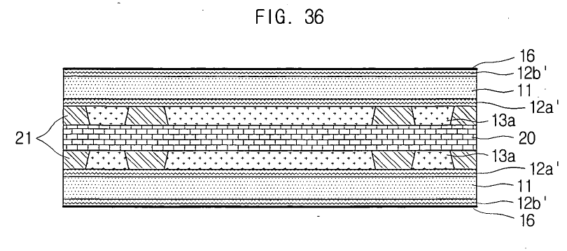

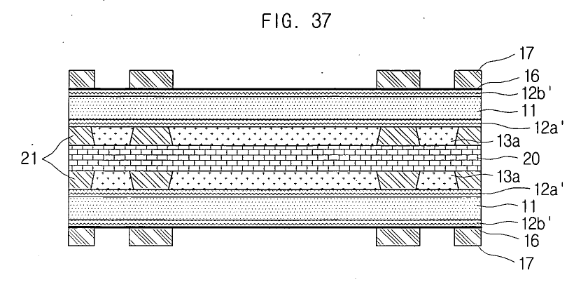

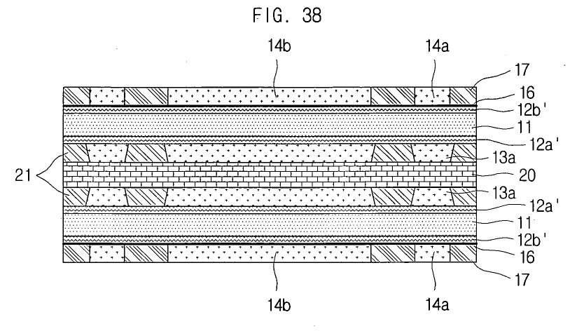

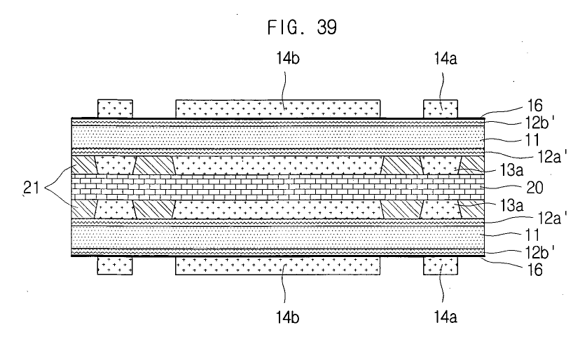

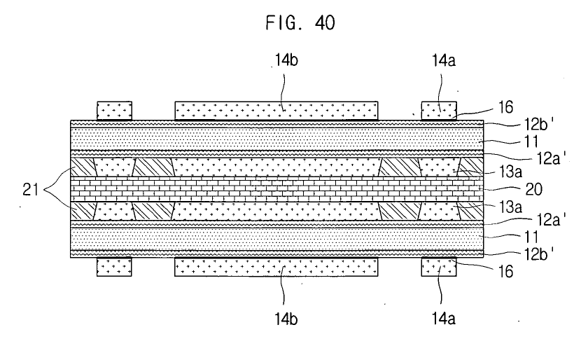

After the desmearing is performed, the second electrode 14a and the second circuit pattern 14b can be formed on the second adhesive resin layer 12b in a step represented by S360. Herein, as shown in FIG. 36, the seed layer 16 can be formed on the second adhesive resin layer 12b in a step represented by S361, and as shown in FIG. 37, the plating resist 17 can be formed on the seed layer 16 in a step represented by S362. Then, as shown in FIG. 38, a plating layer corresponding to the second electrode 14a and the second circuit pattern 14b can be formed through the electroplating in a step represented by S363, and as shown in FIG. 39, the plating resist 17 can be removed in a step represented by S364. Next, as shown in FIG. 40, the flash-etching can be performed to allow some parts of the seed layer 16 to be removed in a step represented by S365. This may be identical to the aforementioned first embodiment.

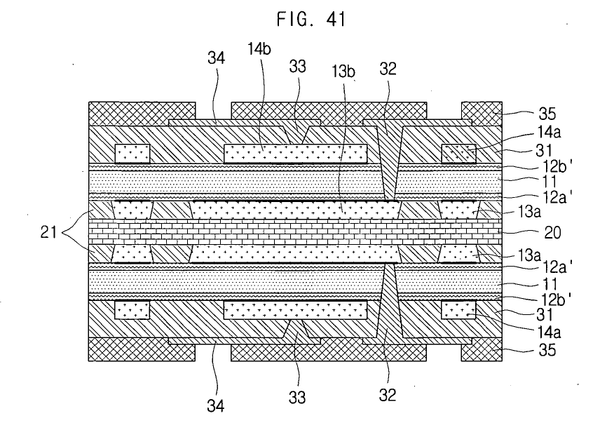

Then, as shown in FIG. 41, the insulation board 31 can be stacked on the substrate to cover the second electrode 14a and the second circuit pattern 14b in a step represented by S370, and the third circuit pattern 34 can be formed on the insulation board 31.

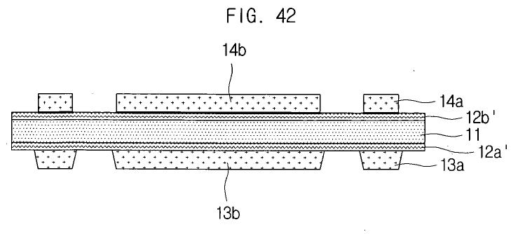

Although this embodiment suggests the method of allowing the substrate in which the first electrode 13a and the second circuit pattern 13b are formed to be stacked on the core board 20 and then the second electrode 14a and the second 14b to be formed, as shown FIG. 42, it may be alternatively possible to allow the first electrode 13a, the first circuit pattern 13b, the second electrode 14a and the second circuit pattern 14b to be formed on the substrate before the substrate is stacked on the core board 20.

Then, a fourth embodiment will be described.

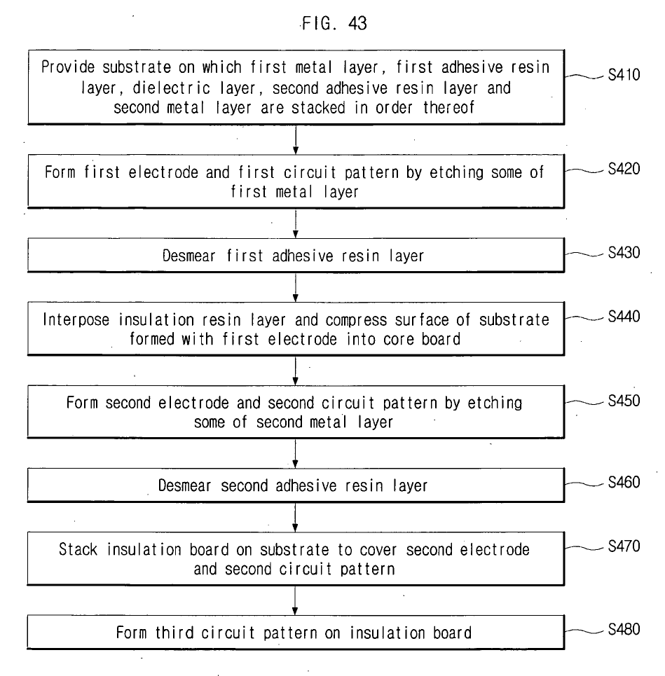

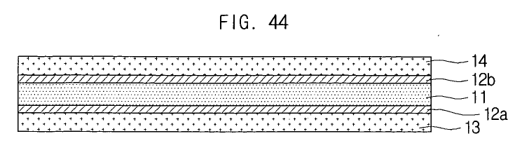

FIG. 43 is a flowchart showing a fourth embodiment of a manufacturing method of a capacitor-embedded printed circuit board in accordance with another aspect of the present invention, and FIG. 44 through FIG. 52 show each process of the manufacturing method of FIG. 43.

Referring to FIG. 44 through FIG. 52, a dielectric layer 11, a first adhesive resin layer 12a and 12a′, a second adhesive resin layer 12b and 12b′, a first metal layer 13, a first electrode 13a, a first circuit pattern 13b, a second metal layer 14, a second electrode 14a, a second circuit pattern 14b, a core layer 20, an insulation resin layer 21, an insulation board 31, a via 32 and 33, a third circuit pattern 34 and an etching resist 35 are shown.

As compared with the above-described third embodiment, the difference is that the second electrode 14a and the second circuit pattern 14b can be formed by an etching method instead of the plating method in accordance with the second embodiment. The below description related to the embodiment focuses on the difference. The description related to identical or corresponding parts will be omitted.

Firstly, as shown in FIG. 44, a substrate in which the first metal layer 13, a first adhesive resin layer 12a, a dielectric layer 11, a second adhesive resin layer 12b and a second metal layer 14 are stacked on the order thereof can be provided in a step represented by S410. As described above, since the second electrode 14a and the second circuit pattern 14b is formed by the etching method in accordance with the embodiment, the substrate in which the second metal layer 14 is stacked on the adhesive resin layer 12 can be used.

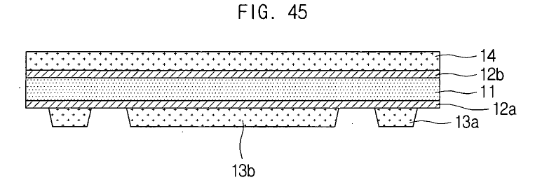

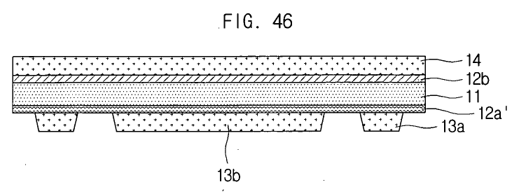

Then, as shown in FIG. 45, the first electrode 13a and the first circuit pattern 13b can be formed by etching some parts of the first metal layer 13 in a step represented by S420. After that, as shown in FIG. 46, the first adhesive layer 12a can be desmeared in a step represented by S430.

Some parts of the first metal layer 13 can be etched to allow some surface of the first adhesive resin layer 12 to be exposed to the outside. The roughness can be formed on the exposed surface of the adhesive resin layer 12. As a result, the formed roughness can make it possible to improve the adhesiveness to the insulation board 31 to be stacked later. This can minimize the possibility of the delamination, to thereby improve the reliability of products. FIG. 46 shows the adhesive resin layer 12′ formed with the roughness.

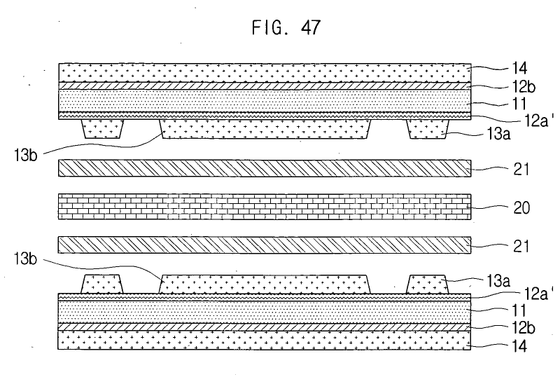

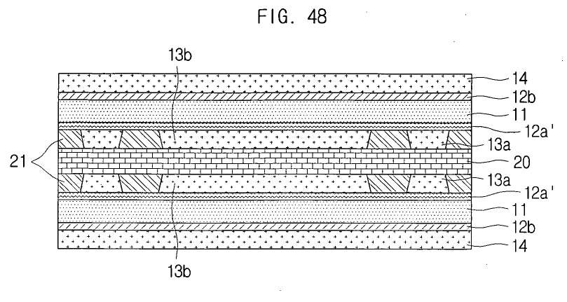

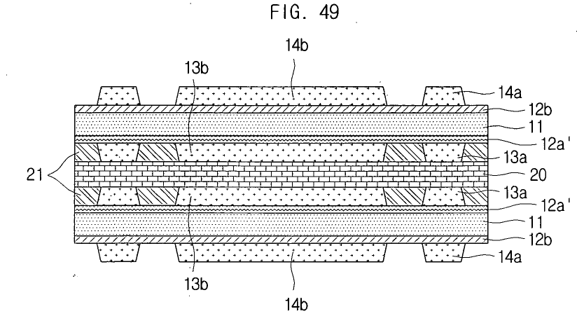

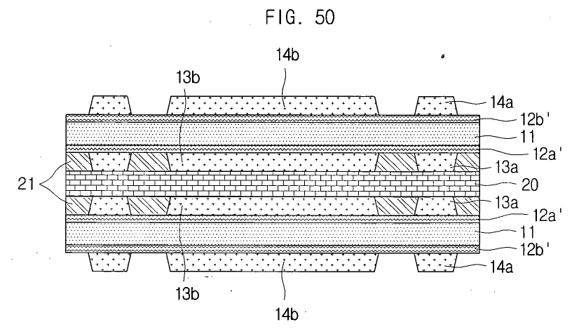

Then, as shown in FIG. 47 and FIG. 48, the insulation resin layer 21 can be interposed to allow a surface of the substrate in which the first electrode 13a is formed to be compressed onto the core board 20 in a step represented by S440, and as shown in FIG. 49, the second electric 14a and the second circuit pattern 14b can be formed by etching some of the second metal layer 14. After than, as shown in FIG. 50, the second adhesive resin layer 12b can also be desmeared in a step represented by S460. FIG. 50 shows the second adhesive resin layer 12b′ formed with the roughness.

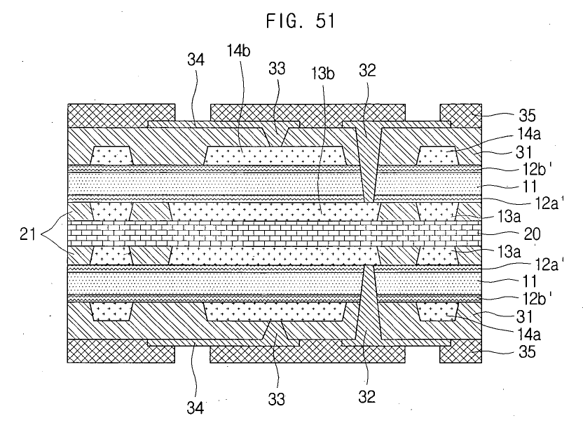

After that, as shown in FIG. 51, the insulation board 31 can be stacked on the substrate to cover the second electrode 14a and the second circuit pattern 14b in a step represented by S470, and the third circuit pattern 34 can be formed on the insulation board 31 in a step represented by S480. In addition to the third circuit pattern 34, the via 32 and 33 can be formed to allow each layer to be electrically connected and the solder resist 35 can be formed in the outermost layer to protect the third circuit pattern 34.

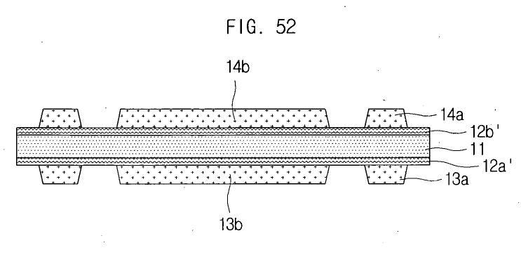

Although this embodiment suggests the method of allowing the substrate in which the first electrode 13a and the second circuit pattern 13b are formed to be stacked on the core board 20 and then the second electrode 14a and the second 14b to be formed, as shown FIG. 52, it may be alternatively possible to allow the first electrode 13a, the first circuit pattern 13b, the second electrode 14a and the second circuit pattern 14b to be formed on the substrate before the substrate is stacked on the core board 20.

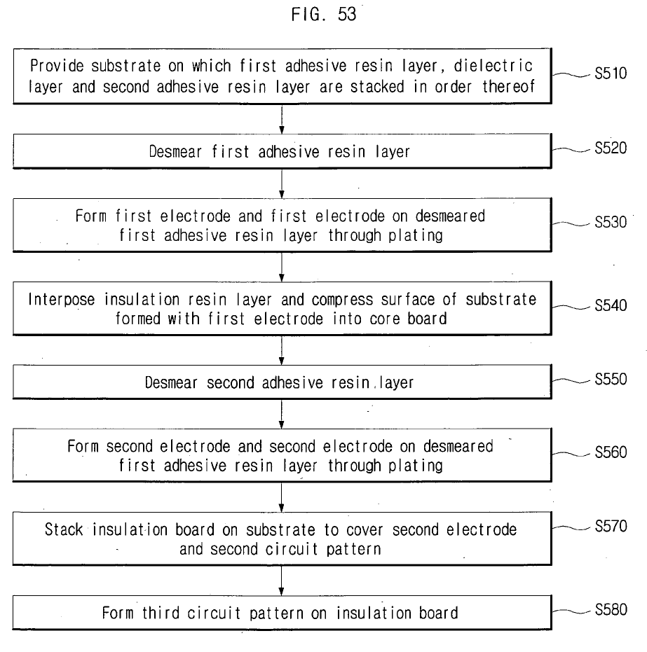

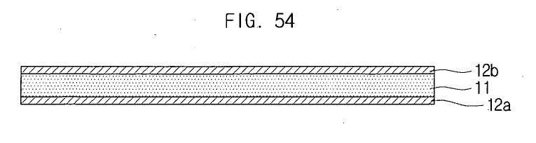

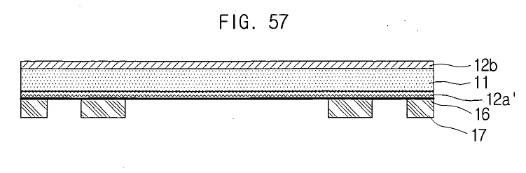

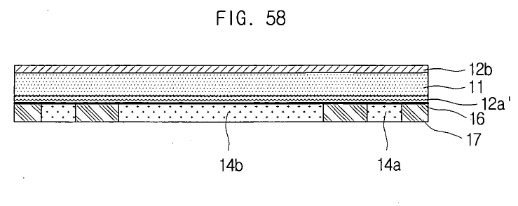

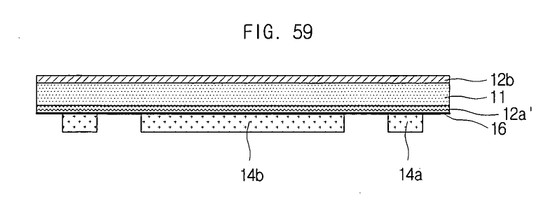

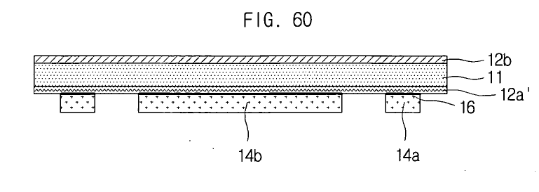

Then, a third embodiment will be described FIG. 53 is a flowchart showing a fifth embodiment of a manufacturing method of a capacitor-embedded printed circuit board in accordance with another aspect of the present invention, and FIG. 54 through FIG. 66 show each process of the manufacturing method of FIG. 53.

Referring to FIG. 54 through FIG. 66, a dielectric layer 11, a first adhesive resin layer 12a and 12′a, a second adhesive resin layer 12b and 12b′, a first electrode 13a, a first circuit pattern 13b, a second electrode 14a, a second circuit pattern 14b, a seed layer 16, a plating resist 17, a core layer 20, an insulation resin layer 21, an insulation board 31, a via 32 and 33, a third circuit pattern 34 and an etching resist 35 are shown.

As compared with the above-described embodiments, the difference is that the first electrode 13a, the first circuit pattern 13b, the second electrode 14a, the second circuit pattern 14b can be formed by the plating method. The below description related to the embodiment focuses on the difference. The description related to identical or corresponding parts will be omitted.

Firstly, as shown in FIG. 54, a substrate in which the first adhesive resin layer 12a, the dielectric layer 11 and the second adhesive resin layer 12b are stacked on the order thereof can be used in a step represented by S510.

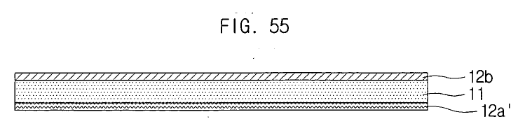

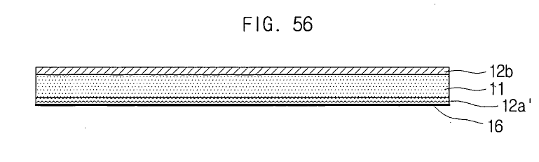

Then, as shown in FIG. 55, the first adhesive resin layer 12a can be desmeared in a step represented by S520, and the first electrode 13a and the first circuit pattern 13b can be formed on the first adhesive resin layer 12a′ that has been desmeared through the plating method in a step represented by S530. In other words, as suggested through the aforementioned embodiment, it can be possible to form the first electrode 13a and the first circuit pattern 13b by using the seed layer 16 and the plating resist 17. This process is described below with reference to FIG. 56 through FIG. 60.

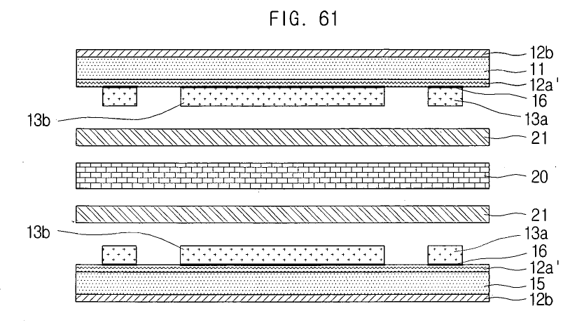

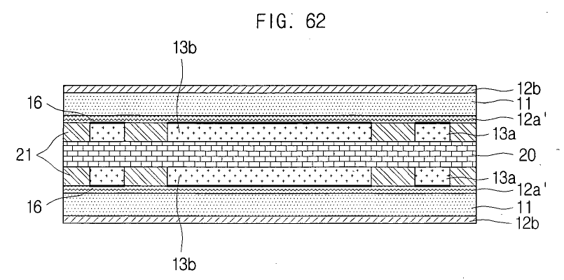

Then, as shown in FIG. 61 and FIG. 62, the insulation resin layer 21 can be interposed to allow a surface of the substrate formed with the first electrode 13a to be compressed onto the core board 20 in a step represented by S540.

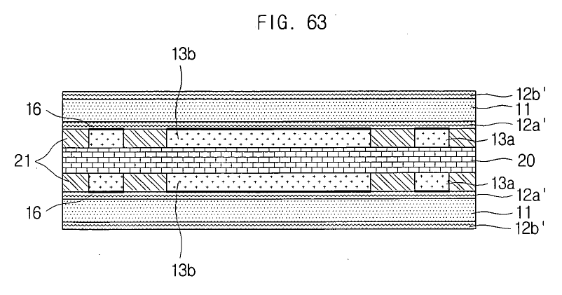

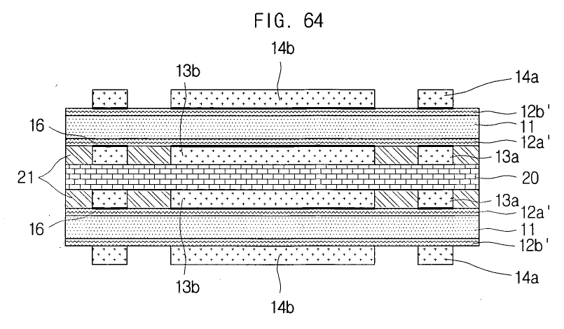

After that, as shown in FIG. 63, the second adhesive resin layer 12b can be desmeared in a step represented by S550, and the second electrode 14a and the second circuit pattern 14b can be formed on the second adhesive resin layer 12b′ that has been desmeared through the plating method in a step represented by S560. Since the second electrode 14a and the second circuit pattern 14b can be formed identically to the first electrode 13a and the first circuit pattern 13b, the pertinent detailed description will be omitted. FIG. 64 shows how the second electrode 14a and the second circuit pattern 14b are formed.

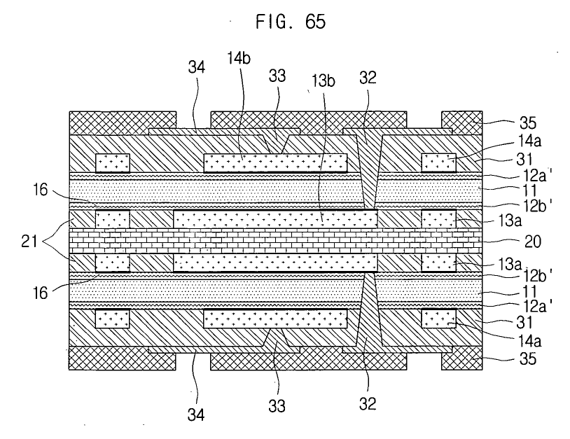

Next, as shown in FIG. 65, the insulation board 31 can be stacked on the substrate to cover the second electrode 14a and the second circuit pattern 14b in a step represented by S570, and the third circuit pattern 34 can be formed on the insulation board 31 in a step represented by S580.

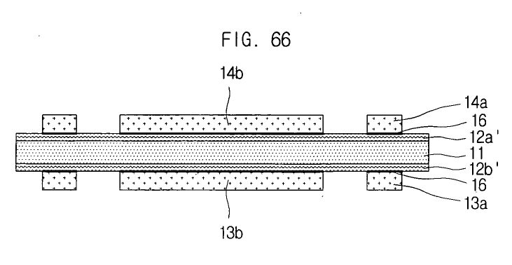

Although this embodiment suggests the method of allowing the substrate in which the first electrode 13a and the second circuit pattern 13b are formed to be stacked on the core board 20 and then the second electrode 14a and the second 14b to be formed, as shown FIG. 66, it may be alternatively possible to allow the first electrode 13a, the first circuit pattern 13b, the second electrode 14a and the second circuit pattern 14b to be formed on the substrate before the substrate is stacked on the core board 20.

Hitherto, although some embodiments of the present invention have been shown and described for the above-described objects, it will be appreciated by any person of ordinary skill in the art that a large number of modifications, permutations and additions are possible within the principles and spirit of the invention, the scope of which shall be defined by the appended claims and their equivalents.

A lot of other embodiments are possible within the principles and spirit of the invention, the scope of which shall be defined by the appended claims and their equivalents.

What is claimed is:

1. A substrate for a capacitor-embedded printed circuit board, the substrate comprising:
a dielectric layer; and
a first adhesive resin layer, configured to be stacked on a surface of the dielectric layer,
wherein roughness is formed on the first adhesive resin layer.

2. The substrate of claim 1, further comprising a second adhesive resin layer, configured to be stacked on another surface of the dielectric layer,
wherein roughness is formed on the second adhesive resin layer:

3. The substrate of claim 2, further comprising a first metal layer, configured to be stacked on the first adhesive resin layer.

4. The substrate of claim 3, further comprising a second metal layer, configured to be stacked on the second adhesive resin layer.

5. A capacitor-embedded printed circuit bard, comprising:
a core board;
an insulation resin layer, configured to be stacked on the core board;
a first electrode and a first circuit pattern, configured to be buried in the insulation resin layer;
a dielectric layer, configured to be stacked on a surface of the insulation resin layer;
a first adhesive resin layer, configured to be stacked on the dielectric layer; and
a second electrode and a second circuit pattern, configured to be formed on a surface of the first adhesive resin layer to correspond with the first electrode.

6. The printed circuit board of claim 5, wherein the first adhesive resin layer is desmeared.

7. The printed circuit board of claim 5, further comprising a second adhesive resin layer, configured to be interposed between the insulation resin layer and the dielectric layer.

8. The printed circuit board of claim 7, wherein the second adhesive resin is desmeared.

9. The printed circuit board of claim 5, further comprising:
an insulation board, configured to be stacked on the first adhesive resin layer to cover the second electrode;
a third circuit pattern, configured to be formed on a surface of the insulation board; and
a via, configured to pass through the insulation board.

10. A method of manufacturing a capacitor-embedded printed circuit board, the method comprising:
providing a substrate on which a first metal layer, a dielectric layer and an adhesive resin layer are stacked on the order thereof;
etching a part of the first metal layer to form a first electrode and a first circuit pattern;
compressing a surface of the substrate, on which the first electrode is formed, onto a core board by interposing an insulation resin layer;
forming a second electrode and a second circuit pattern on the adhesive resin layer;
stacking an insulation board on the substrate such that the second electrode and the second circuit pattern are covered; and
forming a third circuit pattern on the insulation board.

11. The method of claim 10, wherein a second metal layer is stacked on the adhesive resin layer, and in the forming the second electrode and the second circuit pattern, a part of the second metal layer is etched.

12. The method of claim 10, further comprising desmearing the adhesive resin layer, prior to the stacking the insulation board.

13. The method of claim 12, wherein the forming the second electrode and the second circuit pattern comprises:
forming a seed layer on the desmeared adhesive resin layer;
forming a plating resist on the seed layer;
forming a plating layer corresponding to the second electrode and the second circuit pattern through electroplating;
removing the plating resist; and
performing flash-etching such that a part of the seed layer is removed.

14. The method of claim 10, wherein the forming the second electrode and the second circuit pattern is performed before the compressing a surface of the substrate onto a core board.

15. The method of claim 10, wherein two substrates are provided, and
the compressing a surface of the substrate onto a core board is performed on both surfaces of the core board.

16. A method of manufacturing a capacitor-embedded printed circuit board, the method comprising:
providing a substrate on which a first metal layer, a first adhesive resin layer, a dielectric layer and a second adhesive resin layer are stacked on the order thereof;
etching a part of the first metal layer to form a first electrode and a first circuit pattern;
desmearing the first adhesive resin layer;
compressing a surface of the substrate, on which the first electrode is formed, onto a core board by interposing an insulation resin layer;
forming a second electrode and a second circuit pattern on the second adhesive resin layer;
stacking an insulation board on the substrate such that the second electrode and the second circuit pattern are covered; and
forming a third circuit pattern on the insulation board.

17. The method of claim 16, wherein a second metal layer is stacked on the second adhesive resin layer, and in the forming the second electrode and the second circuit pattern, a part of the second metal layer is etched.

18. The method of claim 16, further comprising desmearing the second adhesive resin layer, prior to the stacking the insulation board.

19. The method of claim 18, wherein the forming the second electrode and the second circuit pattern comprises:
forming a seed layer on the desmeared second adhesive resin layer;
forming a plating resist on the seed layer;
forming a plating layer corresponding to the second electrode and the second circuit pattern through electroplating;
removing the plating resist; and
performing flash-etching such that a part of the seed layer is removed.

20. The method of claim 16, wherein the forming the second electrode and the second circuit pattern is performed before the compressing a surface of the substrate onto a core board.

21. The method of claim 16, wherein two substrates are provided, and
the compressing a surface of the substrate onto a core board is performed on both surfaces of the core board.

22. A method of manufacturing a capacitor-embedded printed circuit board, the method comprising:
providing a substrate on which a first adhesive resin layer, a dielectric layer and a second adhesive resin layer are stacked on the order thereof;
desmearing the first adhesive resin layer;
forming a first electrode and a first circuit pattern on the desmeared first adhesive resin layer through a plating process;
compressing a surface of the substrate, on which the first electrode is formed, onto a core board by interposing an insulation resin layer;
forming a second electrode and a second circuit pattern on the second adhesive resin layer;
stacking an insulation board on the substrate such that the second electrode and the second circuit pattern are covered; and
forming a third circuit pattern on the insulation board.

23. The method of claim 22, further comprising desmearing the second adhesive resin layer, prior to the stacking the insulation board,
wherein the forming the second electrode and the second circuit pattern is performed through a plating process.

24. The method of claim 22, wherein the forming the second electrode and the second circuit pattern is performed before the compressing a surface of the substrate on to a core board.

25. The method of claim 22, wherein two substrates are provided, and
the compressing a surface of the substrate is performed on both surfaces of the core board.
